(19) United States
(12) Patent Application Publication
(10) Pub. No.: US 2013/0234325 A1
(43) Pub. Date: Sep. 12, 2013

(54) FILLED THROUGH-SILICON VIA AND THE FABRICATION METHOD THEREOF

(71) Applicant: INDUSTRIAL TECHNOLOGY RESEARCH INSTITUTE, Hsinchu (TW)

(72) Inventors: Ming-Ji Dai, Hsinchu City (TW); Ra-Min Tain, New Taipei City (TW); Chun-Hsien Chien, New Taipei City (TW); Heng-Chieh Chien, New Taipei City (TW); Sheng-Tsai Wu, Taoyuan County (TW)

(73) Assignee: Industrial Technology Research Institute, Hsinchu (TW)

(21) Appl. No.: 13/873,249

(22) Filed: Apr. 30, 2013

Related U.S. Application Data
(63) Continuation-in-part of application No. 13/174,794, filed on Jul. 1, 2011, now Pat. No. 8,456,017.

(30) Foreign Application Priority Data
Apr. 27, 2011 (TW) 100114689

(51) Int. Cl. H01L 23/498

(52) U.S. Cl. CPC H01L 23/49811
USPC 257/737

(57) ABSTRACT

By adding particles of high thermal conductivity and low thermal expansion coefficient into the copper as a composite material and filling with the composite material into the through-via hole, the mismatch of the coefficient of thermal expansion and the stress of the through-silicon via are lowered and the thermal conductivity of the through-silicon via is increased.

### CROSS-REFERENCE TO RELATED APPLICATION

This application is a continuation-in-part application of and claims the priority benefit of U.S. application Ser. No. 13/174,794, filed on Jul. 1, 2011, now allowed, which claims the priority benefit of Taiwan application serial no. 100114689, filed on Apr. 27, 2011. The entirety of the above-mentioned patent applications is hereby incorporated by reference herein and made a part of this specification.

### BACKGROUND

1. Technical Field

The disclosure relates to an electrically connected structure and more particularly to a through-silicon via.

2. Related Art

The semiconductor industry adopts through-silicon vias (TSVs) to connect vertically stacked chips. As a result, the length of the leads between the chips is shortened, the dimension of the devices is reduced, and the three-dimensional stacked framework of the chips is established.

TSV structures require high thermo-mechanical reliability between batches for mass production. Due to the differences in the coefficients of thermal expansion (CTE) of a filling material in the TSVs and of the silicon substrate, the internal stress of the TSVs usually leads to plastic deformation, stress-induced voiding, and stress migration. Furthermore, the stress at the interface of the TSVs causes peeling and popping up of the filled materials (that is so called copper pumps).

Other than thermo-mechanical reliability issues, electrical conductivity of the TSVs should also be taken into consideration. Hence, not only the filling materials for the TSVs but also the filling method applied to fill the TSVs need to be wisely selected to enhance the reliability of TSVs.

### SUMMARY

A through-silicon via (TSV) including at least one through-via hole penetrating a semiconductor wafer or an interposer wafer, an insulation layer and a barrier layer completely covering a sidewall of the through-via hole, and a conductive material filling into the through-via hole and filled the through-via hole covering the insulation layer is introduced herein. The conductive material is a composite material at least including copper and particles of a supplementary material having a coefficient of thermal expansion (CTE) lower than that of copper. The supplementary material is selected from the group consisting of silicon carbide, diamond, beryllium oxide, aluminum nitride, aluminum oxide, and molybdenum.

A stacked chip structure including at least one chip disposed on a substrate is introduced herein. The chip or the substrate includes at least one TSV electrically connecting the chip and the substrate. The TSV includes at least one through-via hole, an insulation layer covering a sidewall of the through-via hole completely, and a conductive material filling into the through-via hole and filled the through-via hole that is covered with the insulation layer. The conductive material is a composite material at least including copper and particles of a supplementary material having a CTE lower than that of copper, where the supplementary material is selected from the group consisting of silicon carbide, diamond, beryllium oxide, aluminum nitride, aluminum oxide, and molybdenum.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1H′ are schematic diagrams illustrating a flowchart for fabricating a through-silicon via (TSV) according to an exemplary embodiment.

FIG. 2 is a schematic diagram illustrating a cross-sectional view of a stacked chip structure according to an exemplary embodiment.

FIG. 2′ is a schematic diagram illustrating a cross-sectional view of a stacked chip structure according to an exemplary embodiment.

FIG. 3 shows a comparison of warpage of a copper-filled TSV and a diamond-copper composite material-filled TSV.

FIG. 4 shows a comparison of Von Mise stress of a copper-filled TSV and a diamond-copper composite material-filled TSV.

FIG. 5 shows a comparison of transmission coefficients S21 of a copper-filled TSV and a diamond-copper composite material-filled TSV.

### DETAILED DESCRIPTION OF DISCLOSED EMBODIMENTS

This disclosure is directed to a though-silicon via (TSV) and a fabrication method thereof, which helps reduce deformation or breakage of TSV caused by mechanical stress and thermal stress and enhance the reliability of the electrical connection of TSVs.

In the specification of this disclosure, a “chip” refers to conventional chips currently used in the electronic or semiconductor field, and includes, but is not limited to, a memory chip, a control chip, or a radio-frequency chip.

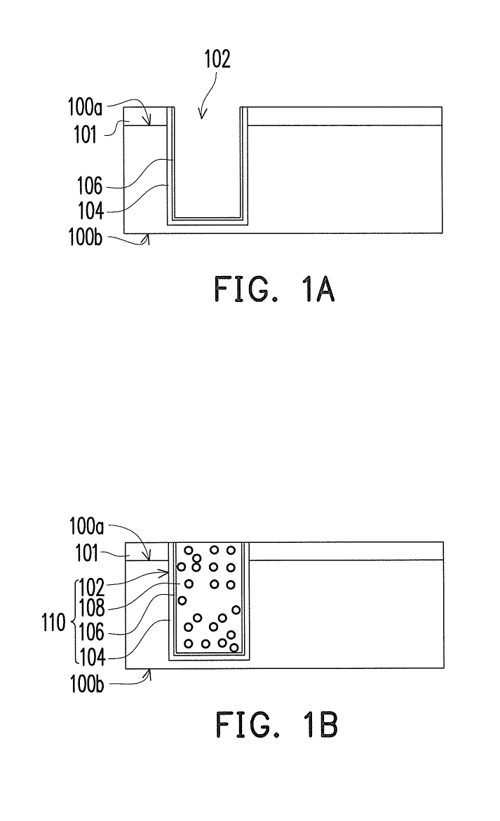

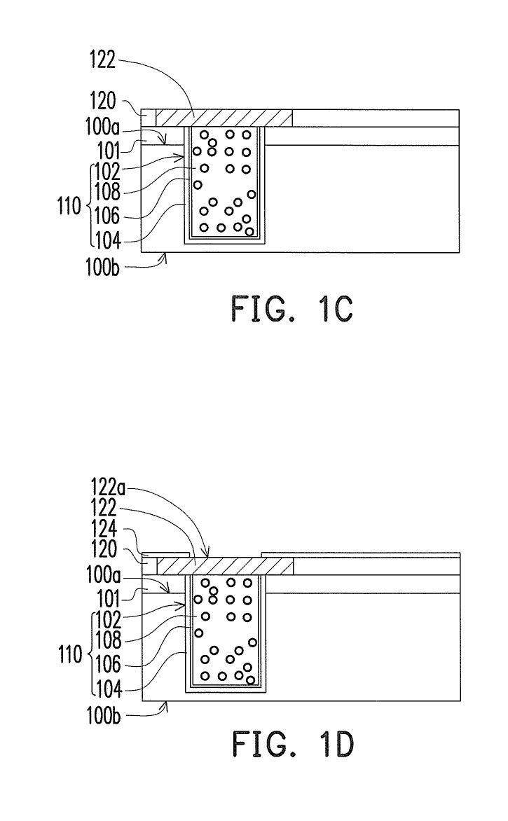

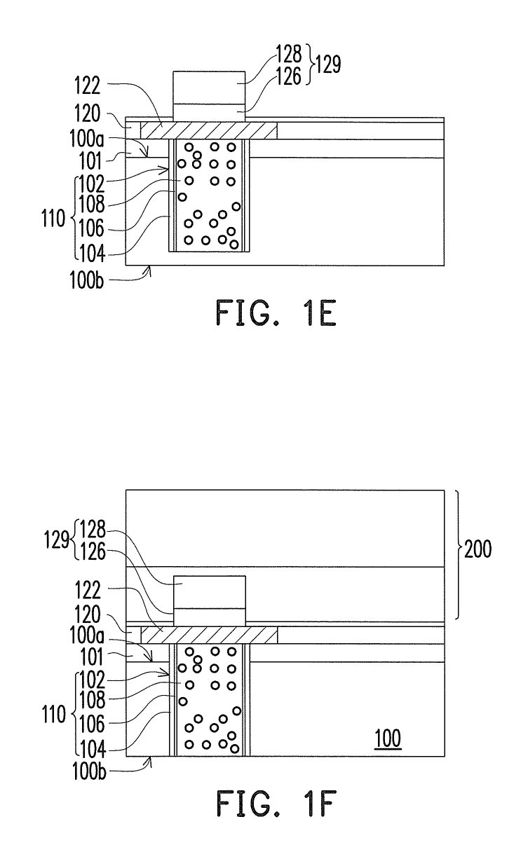

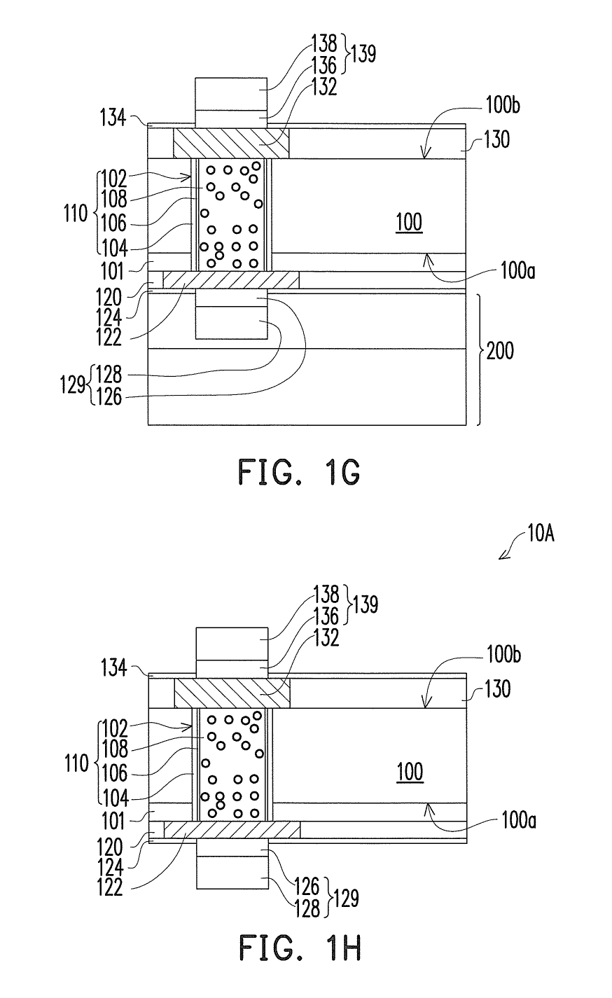

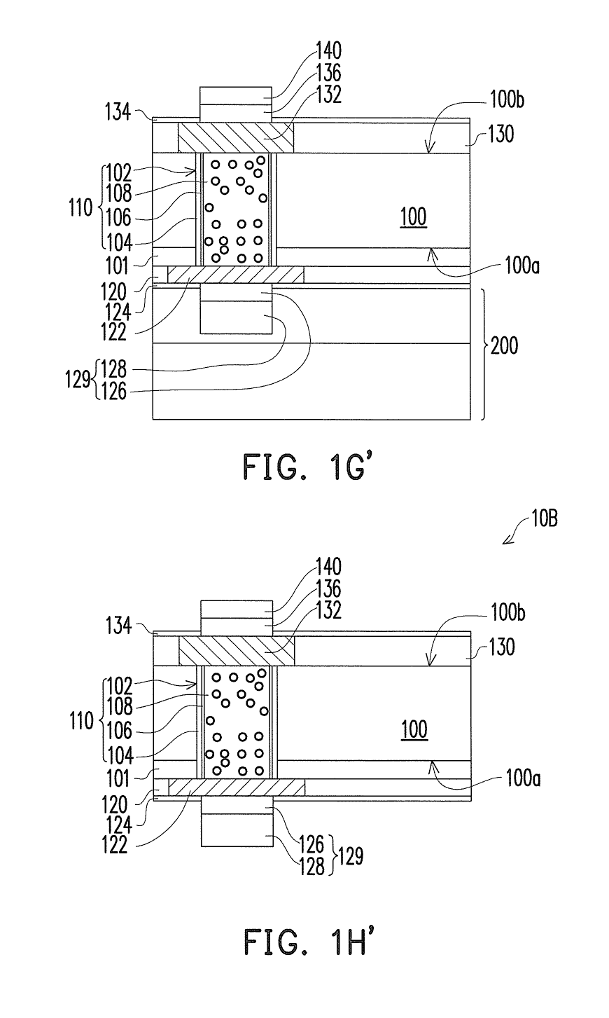

FIGS. 1A to 1H′ are schematic diagrams illustrating a flowchart for fabricating a TSV according to an exemplary embodiment.

Referring to FIG. 1A, one or a plurality of via hole(s) 102 is formed in a substrate 100. Although only one is depicted in the diagram, a plurality of via holes can be formed in rows, columns, or arrays depending on the actual demand. The substrate 100 is a semiconductor wafer, an interposer wafer (such as a silicon wafer or a gallium arsenide wafer, a ceramic substrate or a glass wafer) or other heterogeneous substrates.

An oxide layer 101 is disposed on the upper surface 100a of the substrate 100. If the substrate 100 is an isolative substrate, such as a ceramic substrate or a glass substrate, the formation of the oxide layer 101 may be omitted. The via hole 102 can be formed by a Bosch deep reactive ion etching (Bosch DRIE) process, a cryogenic DRIE process, a laser drilling process, or other anisotropic etching techniques, or even a wet etching process (an isotropic etching process), for example. The fabrication of the via holes 102 particularly desires the uniformity of the size of via hole contours and little or no residues in the via holes. Also, the rate of forming the via holes should meet the demand of relatively high fabrication speeds for mass production. The size or specification of the via holes 102 is determined upon various product demands in different fields. A diameter of the via holes 102 ranges from about 5 to 100 μm and a depth thereof ranges from 10 to 500 μm. The distribution pitch of the via holes 102 is about hundreds to thousands vias per chip.

As shown in FIG. 1A, after the via hole 102 is formed, an insulation layer 104 is deposited on a sidewall of the via hole 102 as an insulation material between the silicon substrate and the subsequently formed conductor. A method of depositing the insulation layer includes a thermal chemical vapor deposition (CVD) method, a plasma enhanced CVD method (PE-CVD), or a low pressure CVD method (LP-CVD). The insulation layer 104 is made of an oxide, a nitride, or a polymer, for example. Since the TSVs of large diameters may have high capacitance and inferior electrical property, a polymer insulation layer with the thickness ranging from about 2 μm to 5 μm can be applied. As the polymer insulation layer with a large thickness is a low dielectric material, the high capacitance problem generated from using conventional insulation films can be alleviated. The polymer is, for example, polyimide (PI). Adopting the polymer insulation layer not only reduces the ratio of copper in the via hole, but also decreases the thermal mechanical stress generated from the large difference between CTEs of silicon and copper. Moreover, the fabrication process of the polymer film is compatible with the wafer back-end processes. If the substrate 100 is an isolative substrate, such as a ceramic substrate or a glass substrate, the formation of the insulation layer 104 may be omitted.

As depicted in FIG. 1A, after the insulation layer 104 is formed, a barrier layer 106 is further formed on the insulation layer 104 to prevent copper diffusion. The barrier layer 106 is generally made of titanium (Ti), tantalum (Ta), or tantalum nitride (TaN), for example.

Referring to FIG. 1B, a conductive material 108 is filled into the via hole 102 to fill up the via hole 102. The conductive material generally used to fill the via hole may be a composite conductive material including a metal material and one or more particles of a thermal conductivity that is larger than that of the metal material and of a CTE that is smaller than that of the metal material. The metal material may be copper (Cu), tungsten (W) or aluminum (Al). Herein, as copper has superior electrical conductivity, the TSV is normally filled with copper using copper electroplating. When the depth of the TSV is not too deep, copper electroplating can fill the via hole completely. However, when the depth of the TSV is deep, since the difference between the coefficient of thermal expansion of silicon (3 ppm/° C.) and the coefficient of thermal expansion of copper (16 ppm/° C.) is huge, the thermal mechanical stress will cause cracks generated between the interior of the TSV and the silicon substrate when copper electroplating is performed to fill the via hole completely. Thus, this disclosure may adopt a copper-based, tungsten-based or aluminum-based composite conductive material as the filling material for the via hole 102. The conductive material 108 is a composite metal material including particles of a supplementary material with high thermal conductivity and low CTE (that is, supplementary material) added to a metal base. The supplementary material with high thermal conductivity and low CTE refers to a material with a CTE lower than that of the base (in terms of the copper-based or aluminum-based composite material, that is, lower than that of copper or of aluminum) and a thermal conductivity higher than that of the base (in terms of the copper-based or aluminum-based composite material, that is, higher than that of copper or of aluminum). Preferably, the CTE of the supplementary material is about lower than 10 ppm/° C. (copper has a CTE of 16.5 ppm/° C., aluminum has a CTE of 23.6 ppm/° C.). The supplementary material here includes, for example, chemical-vapor deposition silicon carbide, diamond, chemical-vapor deposition diamond, beryllium oxide, aluminum nitride, aluminum oxide, molybdenum and/or carbon nanotubes. In the diagram, the circles shown in the conductive material 108 merely represent the added supplementary material particles.

The conductive material 108 can be formed in the via hole 102 through filling, thermal pressing, or co-deposition electroplating. The co-deposition electroplating is performed in the exemplary embodiment; a recipe of the electroplating solution used and a fabrication thereof are illustrated below. Taking the copper-based composite material as an example, a copper sulfate solution (CuSO₂.5H₂O: 210˜240 g/L; H₂SO₄: 50˜70 g/L) is used as an electrolytic solution, with an anode material including phosphorous copper and an anode of a thick copper plate. The second phase material includes particles with high thermal conductivity and low CTE (i.e. supplementary material particles). For instance, the particles can be particles of chemical-vapor deposition silicon carbide, silicon carbide, diamond, chemical-vapor deposition diamond, beryllium oxide, aluminum nitride, aluminum oxide, carbon nanotubes and/or molybdenum, with a particle diameter ranging from about tens of nanometers to tens of micrometers. One or more additive of a suitable amount can be added. For example, three kinds of additives: fluorocarbon surfactant, triethanolamine and hexamethylenetetramine can be mixed in a specific ratio with stirring, so that the second phase is effectively suspended in the electroplating solution.

By adding the second phase particles to prepare the copper-based composite material, not only can the superior electrical conductivity and thermal conductivity of copper be maintained, but better mechanical properties can also be obtained. Additionally, the physical or mechanical performance of the composite material can be modulated by the content of the second phase particles, such that the TSV structure filled by the copper-based composite material can be adjusted according to product demands. The adding ratio of the particles as the second phase material with high thermal conductivity and low CTE is less than or equal to 50% and ranges from about 5% to 50%.

After the via hole 102 is filled with the conductive material 108, a chemical mechanical polishing process or a grinding process is optionally performed to remove the excessive conductive material 108 and/or the barrier layer 106.

At this stage, the fabrication of the basic structure of a filled TSV 110 has been completed. However, further processing is required on a bonding surface of the TSV for connecting vertically stacked chips or devices.

Referring to FIG. 1C, after a first passivation layer 120 is formed, a wiring pattern 122 is formed on the filled via 110 as a redistribution layer.

As shown in FIG. 1D, a patterned second passivation layer 124 is foil red to expose a portion of the wiring pattern 122 (an exposed portion is denoted with 122a) located on the via 110 (108/106/104).

Referring to FIG. 1E, a first under-bump metallization (UBM) structure 129 is formed on the exposed wiring pattern 122a. The first UBM structure 129 includes a copper pad 126 and a bonding pad 128 formed on the copper pad 126. The material of the bonding pad 128 is, for example, nickel/palladium/gold (Ni/Pd/Au) or nickel/gold (Ni/Au).

As shown in FIG. 1F, the substrate 100 is thinned from a lower surface 100b of the substrate 100 until the conductive material 108 in the via 110 (108/106/104) is exposed. In the thinning process, a temporary carrier 200 is utilized to support the substrate 100. The temporary carrier 200, usually a silicon substrate or a glass substrate, is able to fix and then turn over the substrate or the wafer for the other side processing.

As shown in FIG. 1G, the substrate 100 is turned over and the surface 100b faces upwards. The steps described in FIGS. 1C to 1E are repeated to sequentially form a third passivation layer 130 and a fourth passivation layer 134 on the substrate surface 100b. Moreover, a back wiring pattern 132 and a second UBM structure 139 is formed sequentially on the via 108/106/104. The second UBM structure 139 includes a copper pad 136 and a bonding pad 138 formed on the copper pad 136. The material of the bonding pad 138 can be, for example, Ni/Pd/Au or nickel/gold Ni/Au. After the temporary carrier 200 is removed, an interposer structure 10A with at least one TSV 110 penetrating there-through is formed as shown in FIG. 1H.

Alternatively, referring to FIG. 1G′, the third passivation layer 130 and the fourth passivation layer 134 are sequentially formed on the substrate surface 100b, and the back wiring pattern 132, the copper pad 136, and a tin block 140 are formed sequentially on the via 108/106/104. The back wiring pattern 132 can function as a redistribution layer and the copper pad 136 and the tin block 140 can function as micro-bumps. After the temporary carrier 200 is removed, a chip structure 10B with at least one TSV penetrating there-through is formed as shown in FIG. 1H′. A wafer cutting process may be performed after FIG. 1H′ to cut the wafer into a plurality of chips. The subsequent steps are well-known to persons skilled in the art and the details are thus omitted hereinafter.

The structures shown in FIG. 1H and FIG. 1H′ are different in that the potential components or objects connected to the surfaces of the TSVs. If using the interposer structure 10A with at least one TSV in FIG. 1H as an interposer, both surfaces of the substrate 100 can be connected to the chips. The chip structure 10B as shown in FIG. 1H′ has at least one TSV 110 formed within the semiconductor chip, so that one surface of the substrate 100 can be connected to another chip and the other surface can be connected to the interposer or other wiring substrates.

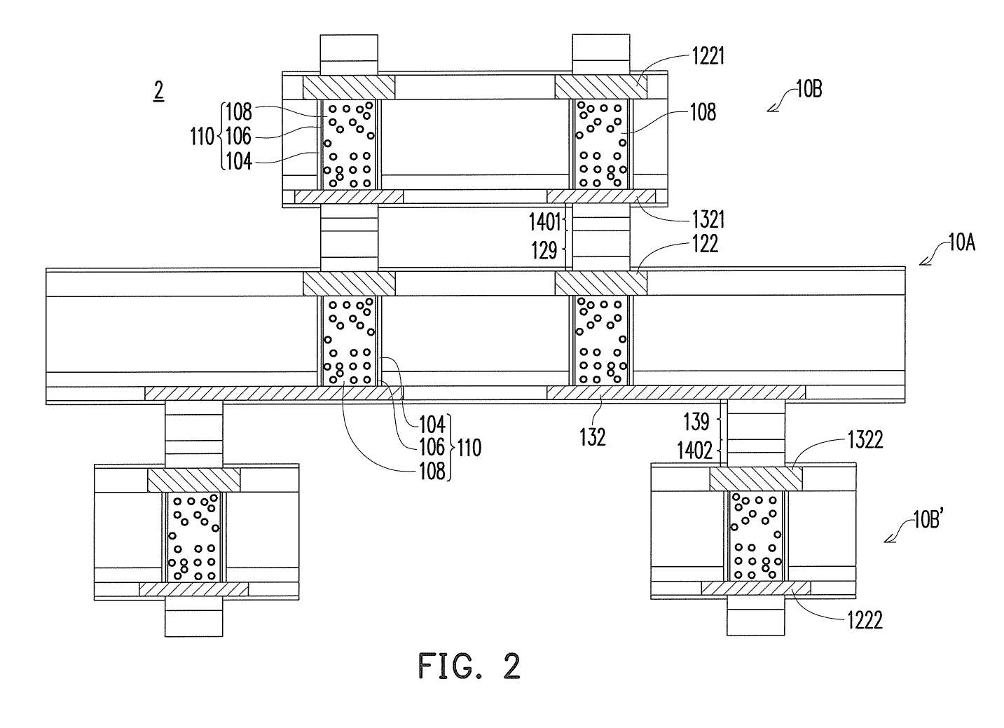

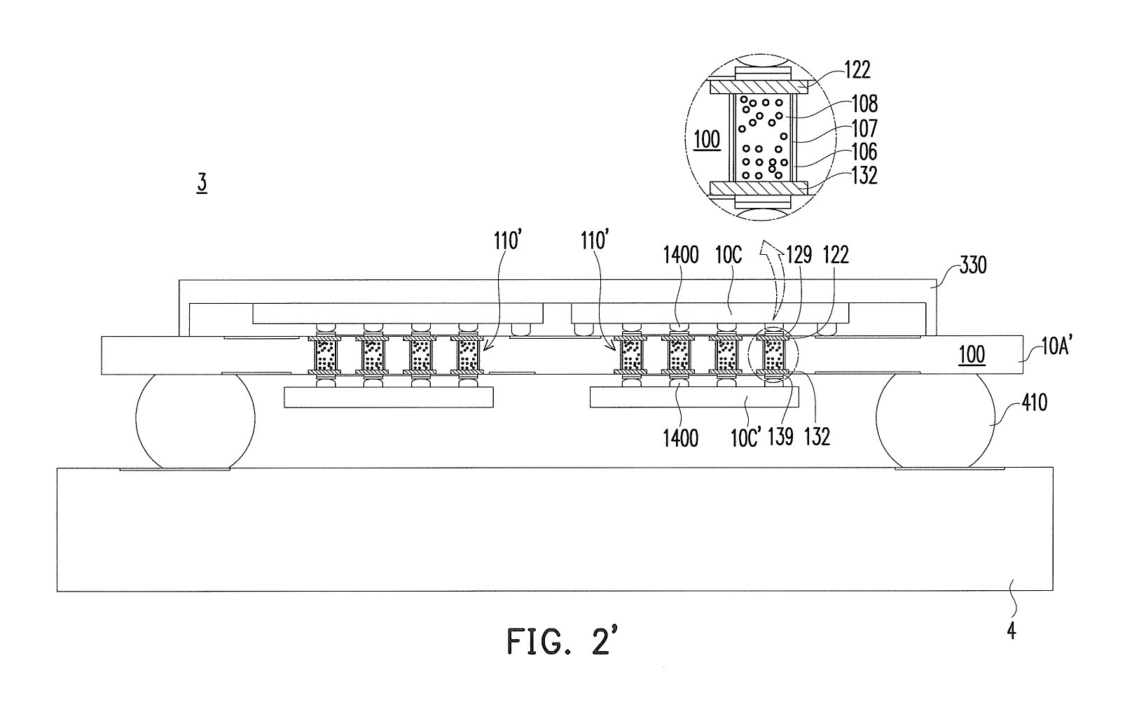

The stacked chip structure in application of the above mentioned TSVs includes at least one or more chips disposed on one or two surfaces of at least one substrate. The chip or the substrate includes at least one TSV which electrically connects the chip and the substrate. FIG. 2 shows a stacked chip structure 2 formed by stacking two chips 10B and 10B′, each having the TSV 110, on both surfaces of the interposer 10A that has at least one TSV 110. On the surfaces of the chips 10B and 10B′ that face the substrate 10A, a plurality of wiring patterns 1321, 1322 covers the conductive material 108 and a plurality of micro-bumps 1401, 1402 located on the wiring patterns 1321, 1322. The chips 10B and 10B′, for instance, are a control chip and a memory chip respectively. The wiring pattern 122 and the back wiring pattern 132 on the two opposite surfaces of the interposer 10A are not identical patterns. The interposer 10A can thus be connected to chip devices of different types or heterogeneous chips conveniently. The UBM structures 129, 139 are respectively disposed on the wiring patterns 122, 132 located on the two opposite surfaces of the interposer 10A.

Hence, chips of different functions or different sizes can be connected through the TSVs and further connected to the substrate or a printed circuit board.

FIG. 2′ shows a stacked chip structure 3 formed by stacking a plurality of chips 10C and a plurality of chips 10C′ (having no TSVs as exemplified herein) on both surfaces of the interposer 10A′. The interposer 10A′ may be an isolative interposer, such as a glass interposer or a ceramic interposer, having a plurality of filled through-vias 110′ therein and penetrating through the substrate 100 of the interposer 10A′, for example. Compared with structure of the TSV 110 shown in FIG. 1B, because the material of the substrate 100 of the interposer 10A′ is an isolative or insulating material (such as a glass or ceramic material), the through-vias 110′ may be formed without forming the oxide layer 101 and the insulation layer 104. After forming the via holes 102 in the substrate 100, it is optional to from a barrier layer 106 and/or a seed layer covering sidewalls of the via holes 102. The barrier layer 106 may be deposited inside the via holes 102 and covering the sidewalls of the via holes 102 to prevent metal (such as copper) diffusion. The barrier layer 106 is generally made of titanium (Ti), tantalum (Ta), or tantalum nitride (TaN), for example. Later, a seed layer 107 may be formed on the barrier layer 106 by sputtering or plating, for example. The seed layer 107 can assist the subsequent formation of the wiring patterns or the filling of the conductive material. The seed layer 107 may be a thin metal layer including copper, titanium (Ti) or the combinations thereof.

The filled through-vias 110′ in FIG. 2′ may be formed by directly filling the conductive material 108 into the via hole 102 to fill up the via hole 102. As exemplified above, the conductive material generally used to fill the via hole may be a composite conductive material including a metal material and one or more particles of a thermal conductivity that is larger than that of the metal material and of a CTE that is smaller than that of the metal material. The metal material may be copper (Cu), tungsten (W) or aluminum (Al). The conductive material 108 is a composite metal material including particles of a supplementary material with high thermal conductivity and low CTE (that is, supplementary material) added to a metal base. The supplementary material with high thermal conductivity and low CTE refers to a material with a CTE lower than that of the base (in terms of the copper-based or aluminum-based composite material, that is, lower than that of copper or of aluminum) and a thermal conductivity higher than that of the base (in terms of the copper-based or aluminum-based composite material, that is, higher than that of copper or of aluminum). The supplementary material here includes, for example, silicon carbide, chemical-vapor deposition silicon carbide, diamond, chemical-vapor deposition diamond, beryllium oxide, aluminum nitride, aluminum oxide, molybdenum and/or carbon nanotubes.

As shown in the enlarged partial view of FIG. 2′, the front wiring pattern 122 and the back wiring pattern 132 cover the two opposite surfaces of the filled through-vias 110′. The chips 10C and 10C′ are connected to the front wiring pattern 122 and the back wiring pattern 132 on the two opposite surfaces of the interposer 10A′. The chips 10C are connected to the front wiring pattern 122 and the UBM structures 129 of the interposer 10A′ through a plurality of bumps 1400 of the chips 10C, while the chips 10C′ are connected to the back wiring pattern 132 and the UBM structures 139 of the interposer 10A′ through a plurality of bumps 1400 of the chips 10C′. The chips 10C′ are control chips and the chips 10C are memory chips respectively disposed on the bottom surface and the top surface of the interposer 10A′, for instance. The front wiring pattern 122 and the back wiring pattern 132 on the two opposite surfaces of the interposer 10A′ may not be identical patterns. The structures and materials of the UBM structures 129, 139 in FIG. 2′ are similar to or the same with the UBM structures 129, 139 in FIGS. 1E-1F. The interposer 10A′ can thus be connected to chip devices of different types or heterogeneous chips conveniently.

In FIG. 2′, the stacked chip structure 3 further includes a heat sink 330 disposed on the top surface of the interposer 10A′ for helping heat dissipation. The stacked chip structure 3 can be connected further connected to an organic substrate or a printed circuit board 4 through a plurality of solder balls 410 located between the organic substrate/printed circuit board 4 and the bottom surface of the interposer 10A′.

In the stacked chip structure 3, heat dissipation of the chips 10C′ may be facilitated or improved by these TSVs 110′ as these TSVs may help transmit the heat generated by the chips 10C′ on the lower surface to the top surface of the interposer 10A′ and then dissipated through the heat sink.

Here, the materials used to fill the TSVs are compared to evaluate whether the requirements of high thermal conductivity and high mechanical performance for the TSVs can be satisfied. The TSV filled with only copper acts as the control to be compared with the TSV filled with a composite material of diamond-Cu (DiCu). The amount of diamond powder added to the composite material accounts for 50% of the total amount. The thermal mechanical simulation parameters resulted from the experiment are shown in Table 1. E represents Young's modules, v represents Poisson's ratio, and the CTE of the silicon at 25° C. and 100° C. as references.

TABLE 1

| | Young's modules | Poisson's | |
|---|---|---|---|
| Material | E (GPa) | ratio v | CTE (ppm/° C.) |
| Silicon | 129.617@25° C. | 0.28 | 2.813@25° C. |
| | 128.425@150° C. | | 3.107@150° C. |
| Silicon oxide | 70 | 0.16 | 0.6 |
| Copper | 110 | 0.35 | 16.5-16.8 |
| Diamond-copper | 55.61 | 0.275 | 12 |
| (50% diamond) | | | |

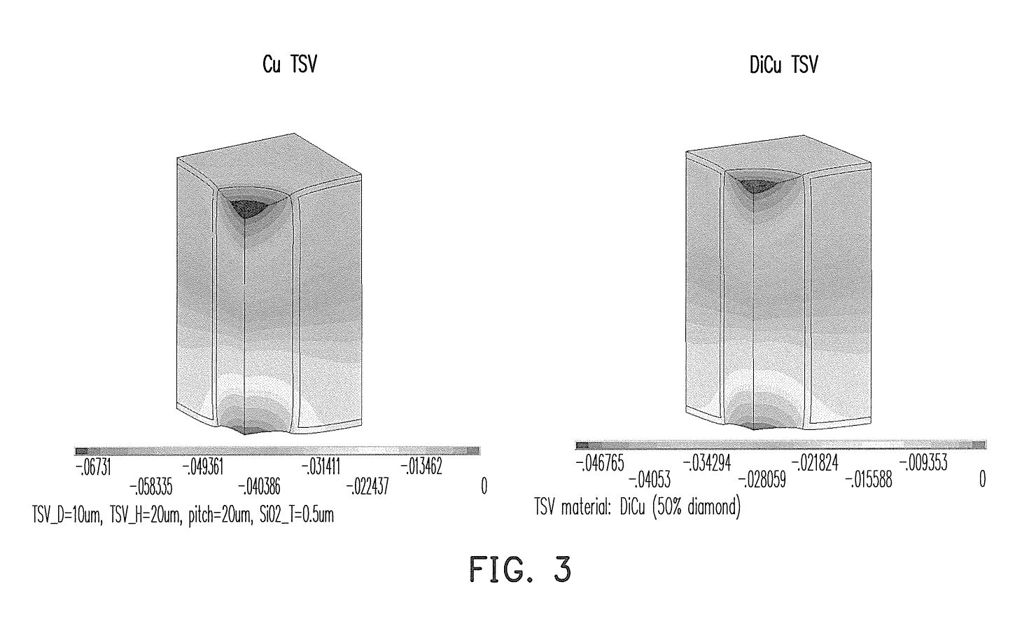

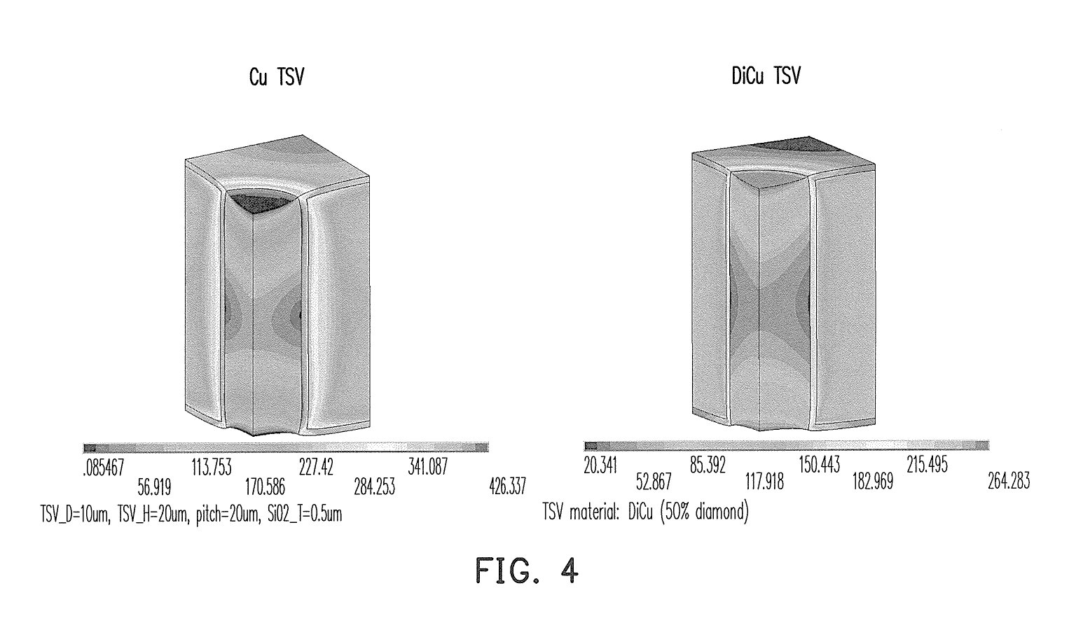

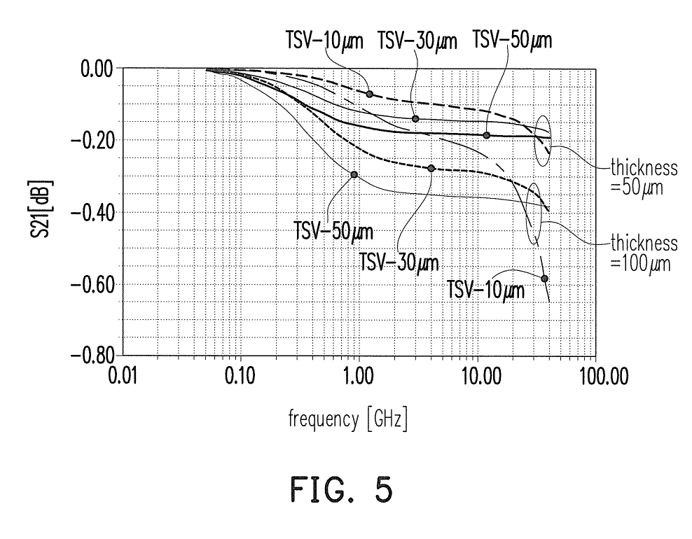

As the CTE mismatch of the TSV filled with the DiCu composite material (denoted as DiCu TSV in the diagram) is less than that of the TSV filled with copper (denoted as Cu TSV in the diagram), the level of warpage can be reduced by 30% and the value of Von Mise stress is lowered by about 40% as depicted in the simulation results shown in FIGS. 3 and 4. The levels of other thermal mechanical properties (such as stress, strain) are also reduced with the addition of diamond powder particles. In terms of electric property simulation, as illustrated in the simulation result in FIG. 5, insertion loss coefficients S21 of Cu TSV and DiCu TSV have insignificant difference in the frequency band of 50 MHz to 40 GHz no matter the TSV has a diameter of 10, 30, or 50 μm. The electrical conductivity of the DiCu composite material is about 10⁷.

The diameter of the TSV should match the size of particles added in the composite material for better thermal conduction. In terms of thermal conduction, when 50% of diamond powder particles are added, the particle size is larger than 60 μm, the thermal conductivity coefficient of the DiCu composite material is larger than 400 W/mK of copper. When the particle size of the diamond powder is smaller than 20 μm, the thermal conductivity coefficient of the DiCu composite material changes with the addition of diamond powder, where a maximum value is achieved when the interface is properly treated. When the diameter of the DiCu TSV is larger than 30 μm, the thermal conductivity coefficient thereof can then be larger than the thermal conductivity coefficient of silicon (k=148 W/mK). Comparing TSVs of different diameters or thicknesses (filling depths), the TSV has higher thermal conductivity as the thickness of silicon decreases.

Comparing the TSV filled with a silicon carbide-copper (SiC—Cu) composite material and the TSV filled with copper, the addition percentage of SiC powder in the composite material is 20% to 30%. The TSV filled with the SiC—Cu composite material has a CTE mismatch smaller than the TSV filled with copper. The TSV filled with the SiC—Cu composite material therefore has higher thermal mechanical reliability.

This disclosure is directed to a TSV using a conductor material of a CTE close to the CTE of silicon. Also, a particle material of high thermal conductivity and low CTE is added to copper to fabricate a copper-based composite material for filling into the TSVs. As a consequence, the thermal mechanical issues of TSVs are solved and the reliability of TSVs is enhanced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A through via, comprising:
at least one through-via hole disposed between a first surface and a second surface opposite to the first surface of an isolative substrate and penetrating the isolative substrate; and
a conductive material filled within the at least one through-via hole and filled up the at least one through-via hole, the conductive material being a composite material at least comprising a metal material and particles of a supplementary material having a coefficient of thermal expansion lower than a coefficient of thermal expansion of the metal material and having a thermal conductivity higher than a thermal conductivity of the metal material, wherein the metal material is selected from copper, tungsten or aluminum, and the supplementary material is selected from silicon carbide, chemical-vapor deposition silicon carbide, diamond, chemical-vapor deposition diamond, beryllium oxide, aluminum nitride, aluminum oxide, molybdenum or carbon nanotubes.

2. The through via as claimed in claim 1, wherein a diameter of the particles of the supplementary material substantially ranges from tens of nanometers to tens of micrometers.

3. The through via as claimed in claim 1, wherein an addition ratio of the particles of the supplementary material is less than or equal to 50%.

4. The through via as claimed in claim 1, wherein an addition ratio of the particles of the supplementary material substantially ranges from 5% to 50%.

5. The through via as claimed in claim 1, further comprising a first wiring pattern located on the first surface and covering the conductive material filled in the at least one through-via hole.

6. The through via as claimed in claim 5, further comprising a first under-bump metallization structure located on the first wiring pattern.

7. The through via as claimed in claim 6, wherein the first under-bump metallization structure comprises a copper pad and a bonding pad.

8. The through via as claimed in claim 1, further comprising a second wiring pattern located on the second surface and covering the conductive material filled in the at least one through-via hole.

9. The through via as claimed in claim 8, further comprising a second under-bump metallization structure located on the second wiring pattern.

10. The through via as claimed in claim 9, wherein the second under-bump metallization structure comprises a copper pad and a bonding pad.

11. The through via as claimed in claim 1, further comprising a barrier layer located within the at least one through-via hole and covering a sidewall of the at least one through-via hole.

12. The through via as claimed in claim 11, further comprising a seed layer disposed on the barrier layer and located between the conductive material and the at least one through-via hole.

13. The through via as claimed in claim 12, wherein a material of the barrier layer comprises titanium (Ti), tantalum (Ta), or tantalum nitride (TaN), while a material of the seed layer comprises titanium or copper.

14. A stacked chip structure, comprising:
at least one chip disposed on an isolative interposer, the isolative interposer comprising a plurality of through vias electrically connecting the at least one chip and the isolative interposer, wherein each of the plurality of through vias comprises:
a through-via hole disposed between a first surface and a second surface opposite to the first surface of the isolative interposer and penetrating through the isolative interposer; and
a conductive material filled within the through-via hole and filled up the through-via hole, the conductive material being a composite material at least comprising a metal material and particles of a supplementary material having a coefficient of thermal expansion lower than a coefficient of thermal expansion of the metal material and having a thermal conductivity higher than a then nal conductivity of the metal material, wherein the supplementary material is selected from silicon carbide, chemical-vapor deposition silicon carbide, diamond, chemical-vapor deposition diamond, beryllium oxide, aluminum nitride, aluminum oxide, molybdenum or carbon nanotubes, and the metal material is selected from copper, tungsten or aluminum.

15. The stacked chip structure as claimed in claim 14, wherein a diameter of the particles of the supplementary material substantially ranges from tens of nanometers to tens of micrometers.

16. The stacked chip structure as claimed in claim 14, wherein an addition ratio of the particles of the supplementary material is less than or equal to 50%.

17. The stacked chip structure as claimed in claim 14, wherein an addition ratio of the particles of the supplementary material substantially ranges from 5% to 50%.

18. The stacked chip structure as claimed in claim 14, further comprising a first wiring pattern covering a surface of the through via and a first under-bump metallization structure located on the first wiring pattern.

19. The stacked chip structure as claimed in claim 18, further comprising a second wiring pattern covering another surface of the through via and a second under-bump metallization structure located on the second wiring pattern.

20. The stacked chip structure as claimed in claim 14, wherein each of the plurality of through vias further comprises a barrier layer located within the through-via hole and covering a sidewall of the through-via hole.

21. The stacked chip structure as claimed in claim 20, wherein each of the plurality of through vias further comprises a seed layer disposed on the barrier layer and located between the conductive material and the through-via hole.

22. The stacked chip structure as claimed in claim 21, wherein a material of the barrier layer comprises titanium (Ti), tantalum (Ta), or tantalum nitride (TaN), while a material of the seed layer comprises titanium or copper.

23. The stacked chip structure as claimed in claim 14, further comprising a heat sink disposed on the isolative interposer.
